(19) United States
(12) Patent Application Publication
(10) Pub. No.: US 2026/0085409 A1
(43) Pub. Date: Mar. 26, 2026

(54) VERTICAL FURNACE AND A METHOD FOR OPERATING THE SAME

(71) Applicant: ASM IP Holding B.V., Almere (NL)

(72) Inventors: Fatma Trabelsi, Leuven (BE); Panagiota Arnou, Leuven (BE); Werner Knaepen, Leuven (BE)

(21) Appl. No.: 19/340,740

(22) Filed: Sep. 25, 2025

Related U.S. Application Data
(60) Provisional application No. 63/699,719, filed on Sep. 26, 2024.

(51) Int. Cl. C23C 16/44; C23C 16/06; C23C 16/455

(52) U.S. Cl. CPC C23C 16/4405; C23C 16/06; C23C 16/45553; C23C 16/45557

(57) ABSTRACT

A method for operating a vertical furnace having a reaction chamber for depositing a molybdenum nitride layer on a plurality of wafers is disclosed. The method includes a molybdenum nitride (MoN) depositing run for depositing the MoN layer; and a cleaning run for cleaning the reaction chamber. The MoN deposition run comprises providing a plurality of wafers in a wafer boat and loading the wafer boat in a substantial vertical direction into the reaction chamber; heating the wall of the reaction chamber; flowing a molybdenum precursor into the reaction chamber; flowing a nitrogen precursor into the reaction chamber to deposit MoN on the wafers in the wafer boat; and removing the plurality of wafers in the wafer boat from the reaction chamber. The cleaning run comprises flowing a cleaning to remove deposited layers in the reaction chamber and the cleaning run is ran every 1 to 10 deposition runs.

### CROSS-REFERENCE TO RELATED APPLICATION(S)

This Application claims the benefit of U.S. Provisional Application 63/699,719 filed on Sep. 26, 2024, the entire contents of which are incorporated herein by reference.

### FIELD OF INVENTION

The present disclosure relates generally to an apparatus and methods for cleaning a reaction chamber after a layer has been deposited on interior walls of the reaction chamber. The present disclosure more specifically relates to using halogen-based radicals for performing the cleaning.

### BACKGROUND OF THE DISCLOSURE

Semiconductor fabrication processes for forming semiconductor device structures, such as, for example, transistors, memory elements, and integrated circuits, are wide ranging and may include deposition processes in vertical furnaces. The deposition processes in the vertical furnace may result in layers such as molybdenum or molybdenum nitride being deposited on a plurality of substrates carried in a wafer boat in the reaction chamber of the vertical furnace.

During the deposition processes, the molybdenum or molybdenum nitride layers may also accumulate on interior walls of the reaction chamber. If too much of these layers accumulate on the walls, adverse effects may occur such as drifting process performance due to temperature irregularities caused by the accumulated layers. In addition, the accumulated layers may cause particles to flake off the interior wall and cause irregularities on processed substrates which may be unwanted.

Traditional preventative reaction chamber maintenance may need periodic replacement of the reaction chamber. This may result in significant down time (on the order of 1 week or more), causing a high loss in production.

Accordingly, vertical furnace and methods for operating the same are desired to clean deposited molybdenum or molybdenum nitride layers from the interior wall of the reaction chamber that does not require replacement of the reaction chamber.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In at least one embodiment of the invention, a method for operating a vertical furnace constructed and arranged with a reaction chamber for depositing a molybdenum nitride layer on a plurality of wafers in the reaction chamber is disclosed. The method comprises: a molybdenum nitride depositing run for depositing the molybdenum nitride layer; and a cleaning run for cleaning the reaction chamber. The deposition run comprises: providing a plurality of wafers in a wafer boat with a wafer handler and loading the wafer boat with a boat loader in a substantial vertical direction into the reaction chamber of the vertical furnace; heating the wall of the reaction chamber; flowing a molybdenum precursor into the reaction chamber; flowing a nitrogen precursor into the reaction chamber to deposit molybdenum nitride on the wafers in the wafer boat; and, removing the plurality of wafers in the wafer boat from the reaction chamber. The cleaning run comprises flowing a cleaning gas to the reaction chamber to remove deposited layers in the reaction chamber. The cleaning run may be ran every 1 to 10 deposition runs.

In at least one embodiment of the invention, the reaction chamber of the vertical furnace may be integral to at least one of: an atomic layer deposition (ALD) reaction system; a chemical vapor deposition (CVD) reaction system; a cross-flow deposition system; a minibatch deposition system; or a spatial ALD deposition system. In all these systems there may be a need to clean away a deposited layer on the interior wall of the reaction chamber. The system may have a cold wall or a hot wall reactor chamber. For a hot wall reaction chamber the cleaning may be preferred every run. For a cold wall reaction chamber cleaning may only be necessary periodically.

In at least one embodiment of the invention the reaction chamber may be purged by flowing a purge gas to remove a by-product of the reaction of the precursors or the cleaning gas from the reaction chamber after flowing the molybdenum precursor, the nitrogen precursor or the cleaning gas into the reaction chamber. Purging circumvents a reaction between (by-products of) the molybdenum precursor, the nitrogen precursor and the cleaning gas.

In at least an embodiment of the invention a vertical furnace for depositing a molybdenum or molybdenum nitride layer may be disclosed. The vertical furnace may comprise: a reaction chamber configured to hold a plurality of substrates and provided with a heater to process the wafers in the wafer boat; a first precursor source configured to provide a molybdenum precursor to the reaction chamber via a first valve; a second precursor source configured to provide a nitrogen precursor to the reaction chamber via a second valve; a cleaning gas source configured to provide a cleaning gas to the reaction chamber via a third valve; a wafer handler to transfer wafer to and from the wafer boat; a boat loader to load and unload the wafer boat in a substantial vertical direction into or out of the reaction chamber of the vertical furnace; and, a controller provided with a memory and constructed and arranged to control the first, second and third valve, the heater, the wafer handler and the boat loader. The memory may be programmed with a program when run on the controller to execute a method comprising: a molybdenum nitride depositing run for depositing the molybdenum nitride layer; and a cleaning run for cleaning the reaction chamber. The memory may be programmed with the deposition run comprising: providing a plurality of wafers in the wafer boat with the wafer handler and loading the wafer boat with the boat loader in a substantial vertical direction into the reaction chamber of the vertical furnace; heating the wall of the reaction chamber; flowing a molybdenum precursor into the reaction chamber; flowing a nitrogen precursor into the reaction chamber to deposit molybdenum nitride on the wafers in the wafer boat; and, removing the plurality of wafers in the wafer boat from the reaction chamber. The memory may be programmed with the cleaning run comprising flowing a cleaning gas to the reaction chamber to remove deposited layers in the reaction chamber and the cleaning run may be ran every 1 to 10 deposition runs. An inert gas may be used for dilution of the precursor and/or cleaning gas. The inert gas may also be used for flushing away the cleaning gas and/or the precursor gas and any reaction by-products. A fourth valve may be used to provide the inert gas. The molybdenum and nitrogen precursor may also be co-flowed in the reaction chamber simultaneously.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1a illustrates a non-limiting exemplary process flow, demonstrating a method for cleaning a molybdenum nitride layer from interior walls of a reaction chamber according to the embodiments of the disclosure.

FIG. 1b illustrates a non-limiting exemplary process flow, demonstrating a method for cleaning a molybdenum nitride layer from interior walls of a reaction chamber according to the embodiments of the disclosure.

FIG. 2 illustrates a cross-sectional schematic diagram of a layer deposition system according to the embodiments of the disclosure.

FIG. 3 illustrates a batch reactor system in accordance with at least one embodiment of the disclosure.

FIG. 4 illustrates a non-limiting exemplary process flow, demonstrating a method for cleaning a molybdenum layer from interior walls of a reaction chamber according to the embodiments of the disclosure.

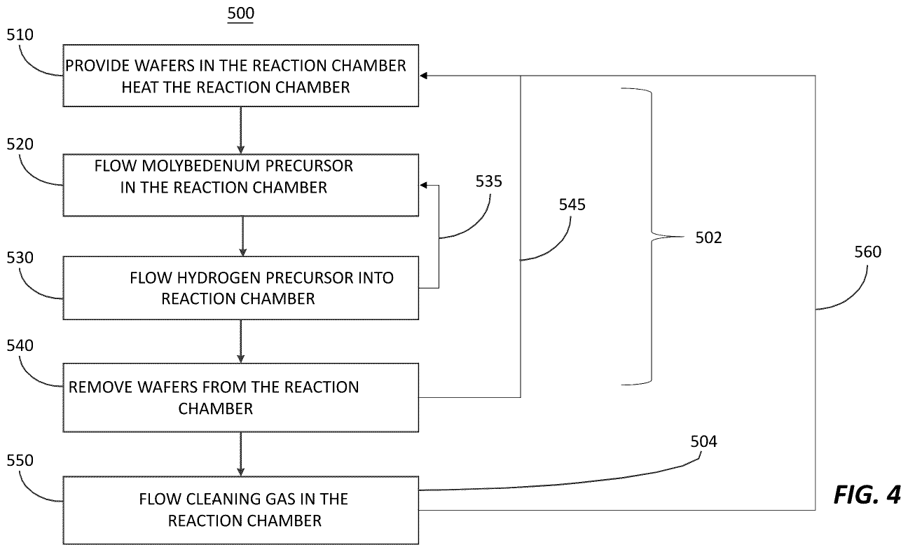

The illustrations presented herein are not meant to be actual views of any particular material, structure, or device, but are merely idealized representations that are used to describe embodiments of the disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials that may be used, or upon which, a device, a circuit, or a layer may be formed.

As used herein, the term “cyclical chemical vapor deposition” may refer to any process wherein a substrate is sequentially exposed to one or more volatile precursors, which react and/or decompose on a substrate to produce a desired deposition.

As used herein, the term molybdenum precursor may refer to a molybdenum halide precursor, such as a molybdenum chloride precursor, a molybdenum iodide precursor, or a molybdenum bromide precursor; or a molybdenum chalcogenide, such as a molybdenum oxychloride, a molybdenum oxyiodide, a molybdenum (IV) dichloride dioxide (MoO₂Cl₂) precursor, or a molybdenum oxybromide.

As used herein, the term nitrogen precursor can refer to a gas or a material that can become gaseous and that can be represented by a chemical formula that includes nitrogen. In some cases, the chemical formula includes nitrogen and hydrogen. In some cases, the nitrogen precursor does not include diatomic nitrogen. The nitrogen precursor may be selected from one or more of ammonia (NH₃), hydrazine (N₂H₄), and other compounds comprising or consisting of nitrogen and hydrogen. For example a mixture of nitrogen gas and hydrogen gas may be used. In an embodiment, the nitrogen precursor does not include diatomic nitrogen, i.e. the nitrogen precursor is a non-diatomic precursor.

In some embodiments, the nitrogen precursor is selected from a group consisting of molecular nitrogen (N₂), ammonia (NH₃), hydrazine (NH₂NH₂) and a hydrazine derivative, such as tert-butylhydrazine. In some embodiments, the nitrogen precursor does not contain carbon, i.e. it is carbon-free. In some embodiments, the nitrogen precursor does not contain silicon, i.e. it is silicon-free. Depending on the selected nitrogen precursor, it may be liquid or gaseous in the precursor vessel upon vaporization. Also solid precursors may be used.

In some embodiments, the nitrogen precursor comprises ammonia. In some embodiments, the nitrogen precursor consists essentially of, or consists of ammonia. In some embodiments the nitrogen precursor comprises an alkylamine. In some embodiments the nitrogen precursor consists essentially of or consists of an alkylamine. Examples of alkylamines include dimethylamine, n-butylamine and tert-butylamine.

In some embodiments, the nitrogen precursor comprises hydrazine. In some embodiments, the nitrogen precursor consists essentially of, or consists of hydrazine. In some embodiments the nitrogen precursor comprises hydrazine substituted by one or more alkyl or aryl substituents. In some embodiments the nitrogen precursor consists essentially of, or consists of hydrazine substituted by one or more alkyl or aryl substituents. In some embodiments, the hydrazine derivative comprises an alkyl-hydrazine including at least one of: tert-butylhydrazine (C₄H₉N₂H₃), methylhydrazine (CH₃NHNH₂), 1,1-dimethylhydrazine ((CH₃)₂NNH₂), 1,2-dimethylhydrazine (CH₃)NHNH(CH₃), ethylhydrazine, 1,1-diethylhydrazine, 1-ethyl-1-methylhydrazine, isopropylhydrazine, phenylhydrazine, 1,1-diphenylhydrazine, 1,2-diphenylhydrazine, N-aminopiperidine, N-aminopyrrole, N-aminopyrrolidine, N-methyl-N-phenylhydrazine, 1-amino-1,2,3,4-tetrahydroquinoline, N-aminopiperazine, 1,1-dibenzylhydrazine, 1,2-dibenzylhydrazine, 1-ethyl-1-phenylhydrazine, 1-aminoazepane, 1-methyl-1-(m-tolyl)hydrazine, 1-ethyl-1-(p-tolyl)hydrazine, 1-aminoimidazole, 1-amino-2,6-dimethylpiperidine, N-aminoaziridine, or azo-tert-butane.

In some embodiments, the nitrogen precursor may comprise ammonium hydroxide (NH₄OH). Without limiting the current disclosure to any specific theory, the use of ammonium hydroxide may lead into the incorporation of oxygen into the deposited material. This may have advantages in some applications of the method.

As used herein the term cleaning gas may refer to a cleaning gas comprising nitrogen trifluoride (NF₃); sulfur hexafluoride (SF₆); carbon tetrafluoride (CF₄); fluoroform (CHF₃); octafluorocyclobutane (C₄F₈); chlorine trifluoride (ClF₃); fluorine (F₂); or a mixture of the above.

As used herein, the term “atomic layer deposition” (ALD) may refer to a vapor deposition process in which deposition cycles, preferably a plurality of consecutive deposition cycles, are conducted in a reaction chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “layer” and “thin layer” may refer to any continuous or non-continuous structures and material formed by the methods disclosed herein. For example, “layer” and “thin layer” could include 2D materials, nanolaminates, nanorods, nanotubes, or nanoparticles, or even partial or full molecular layers, or partial or full atomic layers or clusters of atoms and/or molecules. “Layer” and “thin layer” may comprise material or a layer with pinholes, but still be at least partially continuous.

A number of example materials are given throughout the embodiments of the current disclosure, it should be noted that the chemical formulas given for each of the materials should not be construed as limiting and that the non-limiting example materials given should not be limited by a given example stoichiometry.

The present disclosure includes a vertical furnace and method for cleaning a reaction system that performs a molybdenum layer deposition process. Molybdenum thin layers may be utilized in a number of applications, such as, for example, low electrical resistivity gap-fill, liner layers for 3D-NAND, DRAM word-line features, metal gate, DRAM top electrode, memory, or as an interconnect material in CMOS logic applications.

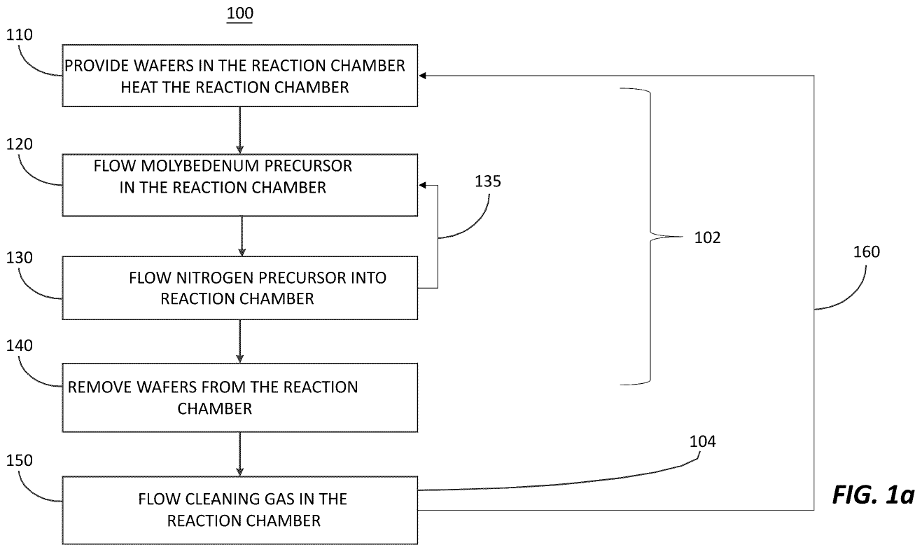

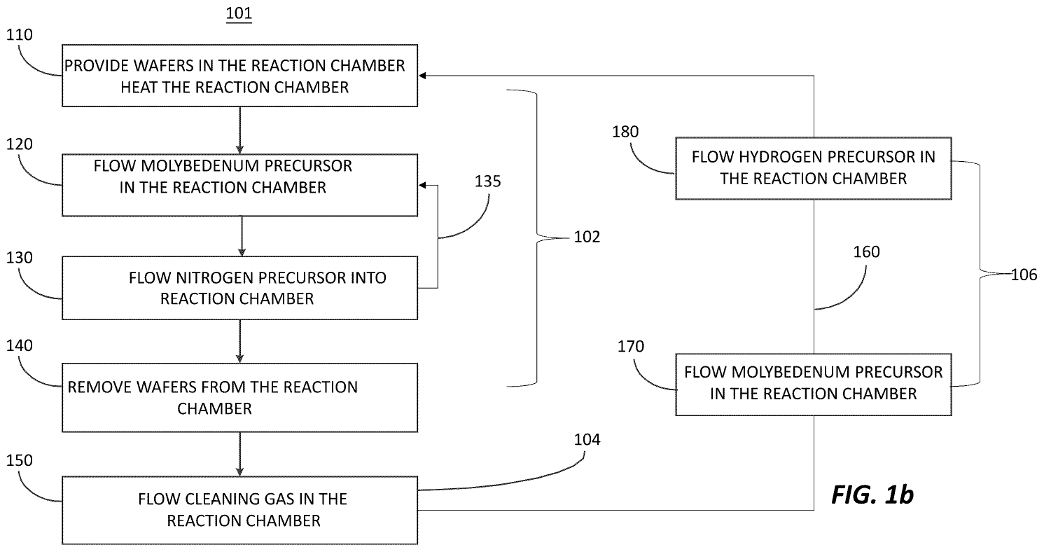

FIG. 1a illustrates a method 100 for operating a vertical furnace in accordance with at least one embodiment of the invention. The method 100 comprises: a molybdenum nitride depositing run 102 for depositing the molybdenum nitride layer; and a cleaning run 104 for cleaning the reaction chamber. The deposition run 102 comprises: providing a plurality of wafers in a wafer boat with a wafer handler, loading the wafer boat with a boat loader in a substantial vertical direction into the reaction chamber of the vertical furnace and heating the wall of the reaction chamber 110. Heating the wall may result in that the temperature of the reaction chamber may be between 450° C. and 650° C., preferably between 500° C. and 600° C. during the molybdenum nitride deposition run. The pressure in the reaction chamber during the deposition run may be between 1 and 200 Torr, preferably between 5 to 100 Torr.

Subsequently, the method comprises flowing a molybdenum precursor into the reaction chamber 120 and flowing a nitrogen precursor into the reaction chamber 130 to deposit molybdenum nitride on the wafers in the wafer boat. The molybdenum precursor may comprise at least one of: a molybdenum halide precursor; a molybdenum chloride precursor; a molybdenum iodide precursor; a molybdenum bromide precursor; a molybdenum chalcogenide; a molybdenum oxychloride; a molybdenum oxyiodide; a molybdenum (IV) dichloride dioxide (MoO₂Cl₂) precursor; or a molybdenum oxybromide. The nitrogen precursor may comprise ammonia (NH₃) or hydrazine (N₂H₄). The flowing of the molybdenum precursor and the nitrogen precursor may be repeated multiple times 135 to get a layer with the required thickness. The deposition run 102 may comprise flowing the molybdenum precursor through a first injector into the reaction chamber and/or flowing the nitrogen precursor through a second injector into the reaction chamber. The reaction chamber may be heated to between 50° and 600° C. for the molybdenum nitride deposition. Using separate injectors for the molybdenum and nitrogen precursor keeps the interion of the injector more clean during the deposition run 102. Providing the nitrogen precursor in the reaction chamber may be followed by providing hydrogen in the reaction chamber. The hydrogen may finalize the reaction of the molybdenum and nitrogen precursor. The molybdenum and nitrogen precursor may also be co-flowed in the reaction chamber simultaneously to provide a CVD like deposition process.

Once a layer with the required thickness is deposited the plurality of wafers in the wafer boat may be removed 140 from the reaction chamber. The wafer may be further processed, such as additional layer deposition processes, cleaning processes, or annealing processes.

In an embodiment removing the plurality of wafers in the wafer boat from the reaction chamber may comprise: removing the boat with wafers in a substantial vertical direction from the reaction chamber of the vertical furnace; removing the wafers from the boat; and, loading the (empty) boat in a substantial vertical direction into the reaction chamber of the vertical furnace. Loading the empty boat before the cleaning run may result in the boat being cleaned from deposited layers during the cleaning run which may be advantageously. The boat may also be cleaned separately by leaving it out of the reaction chamber during the cleaning run 104.

The deposited layer in step 120 and 130 may comprise molybdenum and/or molybdenum nitride. A cleaning run with a cleaning gas may be needed to remove the deposited layer of the inner wall of the reaction chamber. The cleaning gas may comprise at least one of: nitrogen trifluoride (NF₃); sulfur hexafluoride (SF₆); carbon tetrafluoride (CF₄); fluoroform (CHF₃); octafluorocyclobutane (C₄F₈); chlorine trifluoride (ClF₃); fluorine (F₂); or a mixture of the above. The cleaning run may comprise flowing the cleaning gas to the reaction chamber 150 to remove deposited layers, such as the molybdenum and/or molybdenum nitride layer in the reaction chamber. The cleaning run 104 may comprise flowing the cleaning gas through a third injector into the reaction chamber.

The deposition run 102 may also comprise flowing the molybdenum precursor through a first injector into the reaction chamber; and, flowing the nitrogen precursor through the same first injector into the reaction chamber, and the cleaning run 104 comprises flowing the cleaning gas through the same first injector into the reaction chamber in this way the interior of the injector gets well cleaned by the cleaning gas and the design of the vertical furnace is more simple with only one injector needed.

The cleaning run 104 may be ran every 1 to 10, preferably every 1 to 5 deposition runs 102. For molybdenum nitride it may be preferred to clean the reaction chamber every deposition run 102. The deposited molybdenum nitride layer may flake off the inner wall of the reaction chamber in the next run causing particles to be deposited on the wafers which is unwanted and flaking may already occur after the first deposition run 102 of molybdenum nitride. The vertical furnace may be constructed and arranged with a device measuring the remaining thickness of the layer deposited in the reaction chamber during the cleaning run. The cleaning run 104 may be stopped by stopping the flow of the cleaning gas when the measured thickness of the layer deposited in the reaction chamber is substantially zero. This may circumvent over etching of the interior wall of the reaction chamber. The cleaning run may take 2 to 3 hours. After the cleaning run 104 the reaction chamber is ready 160 for the next deposition run 102.

The reaction chamber may be purged by flowing a purge gas to remove the precursors, the cleaning gas or a by-product thereof from the reaction chamber after flowing the molybdenum precursor 120, the nitrogen precursor 130 or the cleaning gas 150 into the reaction chamber. Flowing a purge gas may improve the particle performance of the system since no direct reactions between the molybdenum precursor, the nitrogen precursor or the cleaning gas may then occur in the reaction chamber. The purge gas may comprise at least one of: argon; xenon; helium; or nitrogen.

FIG. 1b illustrates a method 101 for operating a vertical furnace in accordance with at least one embodiment of the invention. The method 101 comprises: a molybdenum nitride depositing run 102 for depositing molybdenum; and a cleaning run 104 for cleaning the reaction chamber similar to the embodiment of FIG. 1. Added thereto is a conditioning run 106 which comprises providing a flow of molybdenum precursor 170 and flowing hydrogen precursor 180 in the reaction chamber to provide a molybdenum layer in the reaction chamber after the cleaning run 104 to condition the reaction chamber. The deposited molybdenum layer has a low tensile stress which decreases flaking off particles in the later process improving the particle performance of the vertical furnace. After the condition run 106 the reaction chamber is ready to receive wafers for the next deposition run 102. Optionally, the conditioning run may comprise depositing a molybdenum nitride layer in the reaction chamber.

Reactors or reaction chambers suitable for performing the embodiments of the disclosure may include ALD reactors, as well as CVD reactors, configured to provide the precursors. According to some embodiments, a showerhead reactor may be used. According to some embodiments, single-wafer, cross-flow, batch, minibatch, or spatial ALD reactors may be used. In some embodiments of the disclosure, a batch reactor may be used. In some embodiments, a vertical batch reactor may be used which may carry up to 200 wafers in one go. In other embodiments, a batch reactor comprises a minibatch reactor configured to accommodate 10 or fewer wafers, 8 or fewer wafers, 6 or fewer wafers, 4 or fewer wafers, or 2 or fewer wafers.

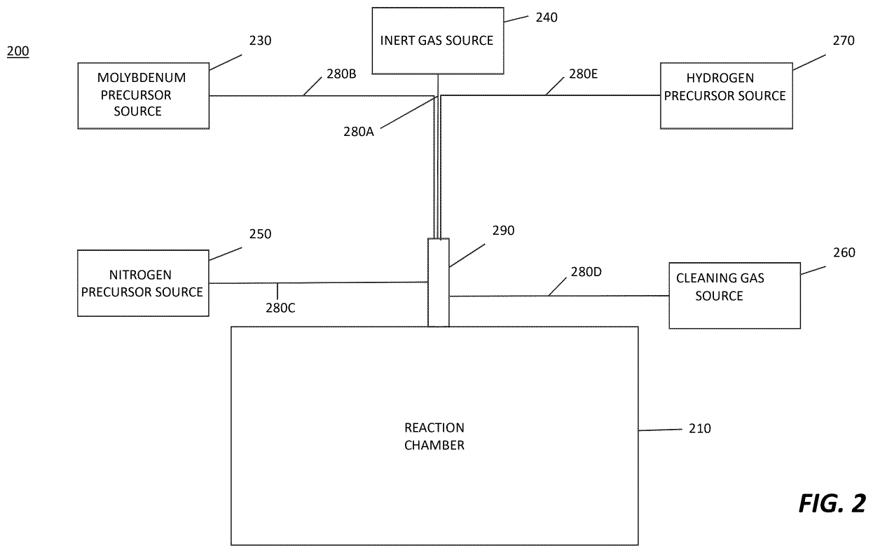

FIG. 2 illustrates a reaction system 200 in accordance with at least one embodiment of the invention. The reaction system 200 may comprise: a reaction chamber 210; a molybdenum precursor source 230; an inert gas source 240; a nitrogen precursor source 250; a cleaning gas source 260; an hydrogen precursor source 270; a series of gas lines 280A-280E; and a main gas line 290.

The reaction chamber of the vertical furnace may be integral to at least one of: an atomic layer deposition (ALD) reaction system; a chemical vapor deposition (CVD) reaction system; a cross-flow deposition system; a minibatch deposition system; or a spatial ALD deposition system. The reaction chamber 210 may have a shape and constitution depending on the type of reaction system 200 employed, whether it be a batch, single-wafer, or mini-batch tool, for example. The shape and constitution of the reaction chamber 210 may also depend on a process employed in the reaction system 200; for example, whether the process is an ALD or a CVD process.

The cleaning gas from the cleaning gas source 260 may comprise at least one of: nitrogen trifluoride (NF₃); sulfur hexafluoride (SF₆); carbon tetrafluoride (CF₄); fluoroform (CHF₃); octafluorocyclobutane (C₄F₈); chlorine trifluoride (ClF₃); fluorine (F₂); or a mixture of the above.

The precursors and the cleaning gas may travel to the reaction chamber 210 via the main gas line 290. The main gas line 290 may also comprise an injector system if the reaction system 200 is a batch or a mini-batch system. The main gas line 290 may also comprise a manifold, a showerhead, or an injection flange for a single-wafer system.

The reaction system 200 may also comprise a molybdenum precursor source 230 that provides a flow of molybdenum precursor to the reaction chamber 210 via the gas line 280B and a first valve therein in order to deposit a molybdenum layer or a molybdenum nitride layer. The molybdenum precursor may comprise at least one of: a molybdenum halide precursor, such as a molybdenum chloride precursor, a molybdenum iodide precursor, or a molybdenum bromide precursor; or a molybdenum chalcogenide, such as a molybdenum oxychloride, a molybdenum oxyiodide, a molybdenum (IV) dichloride dioxide (MoO₂Cl₂) precursor, or a molybdenum oxybromide.

The reaction system 200 may also comprise a nitrogen precursor source 250 that provides a reactant precursor via the gas line 280C and a second valve therein. The inert gas source 240 may provide a purge gas, the purge gas may be utilized to remove precursors in the reaction chamber 210. If the nitrogen precursor source 250 provides a nitrogen precursor, the nitrogen precursor may react with the molybdenum precursor from the molybdenum precursor source 230 to deposit the molybdenum nitride layer.

The reaction system 200 may also comprise a hydrogen precursor source 270 that provides hydrogen via the gas line 280E and a third valve provided therein and flows to the reaction chamber 210, where it may react with the molybdenum precursor to deposit the molybdenum layer. The molybdenum deposition may be needed for the condition run 106 in FIG. 1b.

The reaction system 200 may be provided with a controller with a memory and constructed and arranged to control the first, second and third valve, the heater, the wafer handler and the boat loader, wherein the memory is programmed with a program when run on the controller to execute a method according to FIGS. 1 and 2.

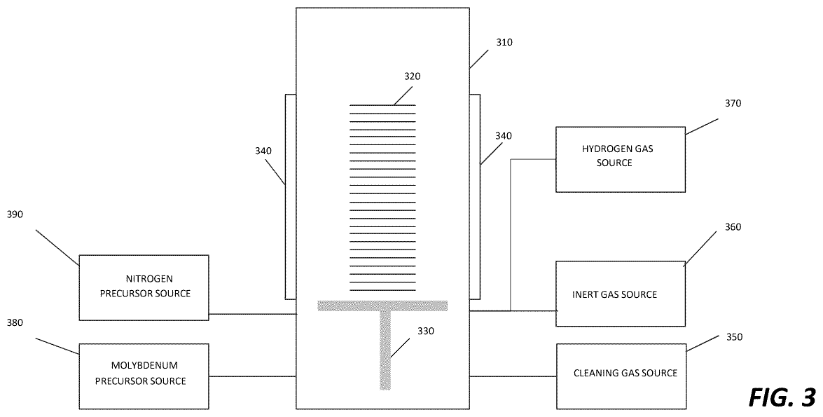

In at least one embodiment of the disclosures, a batch reactor system may be cleaned of a molybdenum or molybdenum nitride layer deposited inside a reaction chamber (or tube). FIG. 3 illustrates a batch reactor system 300 in accordance with at least one embodiment of the invention. The batch reactor system 300 may comprise: a reaction tube 310; a wafer boat 320; a wafer boat holder 330; a cleaning gas source 350; an inert gas source 360; a molybdenum precursor source 380; and a nitrogen precursor source 390.

The reaction tube 310 may comprise quartz and defines a reaction space in which a molybdenum layer or a molybdenum nitride layer is deposited on wafers disposed within the wafer boat 320. The wafer boat holder 330 holds the wafer boat 320 and moves wafers into and out of the reaction tube 310. During the cleaning process, it may be preferable that the wafer boat 320 be inside of the reaction tube 310 to be cleaned as well or outside the reaction tube 310 since it is easily replaceable.

The heater 340 may be used to heat the reaction tube 310. The cleaning gas source 350 may provide a cleaning gas to the reaction tube 310 via gas line and an injector structure. The cleaning gas may comprise at least one of: nitrogen trifluoride (NF₃); chlorine trifluoride (ClF₃); fluorine (F₂); chlorine (Cl₂); or combinations of the above. The cleaning gas may be used to etch a layer of metallic molybdenum or molybdenum nitride formed on the quartz of the reaction tube 310. The flow of the halide gas may range between 10 sccm and 700 sccm, between 50 sccm and 600, or between 100 and 300 sccm. The flow rate of the cleaning gas should be such that damage to an interior of the reaction tube 310 is limited when the cleaning gas is heated. The temperature within the reaction tube 310 during the clean process may be between 300° C. and 500° C., preferably between 350° C. and 450° C. The pressure within the reaction tube 310 during the cleaning run may be between 100 and 2000 millitorr, preferably between 200-1500 millitorr.

The inert gas source 360 may provide an inert gas to the reaction tube 310 via a gas line and injector structure. The inert gas may comprise at least one of: argon; xenon; nitrogen; or helium. The inert gas may be used to purge out any by-products from the reaction of the precursors or cleaning gas with the deposited molybdenum or molybdenum nitride layers on the reaction tube 310. This process may allow for a greater selectivity to etch or clean the molybdenum or molybdenum nitride deposited on quartz in comparison to molybdenum or molybdenum nitride deposited on other surfaces.

FIG. 5 illustrates a method 500 for operating a vertical furnace in accordance with at least one embodiment of the invention. The method 500 comprises: a molybdenum depositing run 502 for depositing molybdenum; and a cleaning run 504 for cleaning the reaction chamber. The method may be used to deposit a molybdenum layer on top of the molybdenum nitride layer obtained in accordance with FIG. 1a. The molybdenum deposition run 502 may comprise: providing a plurality of wafers in a wafer boat with a wafer handler, loading the wafer boat with a boat loader in a substantial vertical direction into the reaction chamber of the vertical furnace and heating the wall of the reaction chamber 510. Subsequently, the method comprises flowing a molybdenum precursor into the reaction chamber 520 and flowing a hydrogen precursor into the reaction chamber 530 to deposit molybdenum on the wafers in the wafer boat. The flowing of the molybdenum precursor and the hydrogen precursor may be repeated multiple times 535 to get a layer with the required thickness. Once a layer with the required thickness is deposited the plurality of wafers in the wafer boat may be removed 540 from the reaction chamber. The wafer may be further processed, such as additional layer deposition processes, cleaning processes, or annealing processes. Once the wafers are removed 540 the molybdenum deposition run 502 may be repeated 545 on a new batch of wafers provided to the reaction chamber 510.

The deposited layer in step 520 and 530 may comprise molybdenum. A cleaning run 504 may be needed to remove the deposited layer of the inner wall of the reaction chamber. The cleaning run may comprise flowing a cleaning gas to the reaction chamber 550 to remove deposited layers, such as the molybdenum layer in the reaction chamber and the cleaning run may be ran every 1 to 10, preferably every 1 to 5, or even more preferably every 1 deposition run 102. If the deposited molybdenum layer gets very thick it may flake off the inner wall of the reaction chamber in the next run causing particles to be deposited on the wafers which is unwanted. After the cleaning run 504 the reaction chamber is ready 560 for the next deposition run 102.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A method for operating a vertical furnace constructed and arranged with a reaction chamber for depositing a molybdenum nitride layer on a plurality of wafers in the reaction chamber, the method comprising a molybdenum nitride depositing run for depositing the molybdenum nitride layer; and a cleaning run for cleaning the reaction chamber, the molybdenum nitride deposition run comprising:
providing a plurality of wafers in a wafer boat with a wafer handler and loading the wafer boat with a boat loader in a substantial vertical direction into the reaction chamber;
heating a wall of the reaction chamber;
flowing a molybdenum precursor into the reaction chamber;
flowing a nitrogen precursor into the reaction chamber to deposit molybdenum nitride on the wafers in the wafer boat; and,
removing the plurality of wafers in the wafer boat from the reaction chamber;
wherein the cleaning run comprises flowing a cleaning gas to the reaction chamber to remove deposited layers in the reaction chamber and the cleaning run is ran every 1 to 10 molybdenum nitride deposition runs.

2. The method of claim 1, wherein the reaction chamber of the vertical furnace is integral to at least one of: an atomic layer deposition (ALD) reaction system; a chemical vapor deposition (CVD) reaction system; a cross-flow deposition system; a minibatch deposition system; or a spatial ALD deposition system.

3. The method of claim 1, wherein the reaction chamber is purged by flowing a purge gas to remove the precursors, the cleaning gas or a by-product from the reaction chamber after flowing the molybdenum precursor, the nitrogen precursor or the cleaning gas into the reaction chamber.

4. The method of claim 1, wherein the cleaning gas comprises at least one of: nitrogen trifluoride (NF₃); sulfur hexafluoride (SF₆); carbon tetrafluoride (CF₄); fluoroform (CHF₃); octafluorocyclobutane (C₄F₈); chlorine trifluoride (ClF₃); fluorine (F₂); or a mixture of the above.

5. The method of claim 1, further comprising a molybdenum deposition run after the molybdenum nitride deposition run, the molybdenum deposition run comprising:
flowing a molybdenum precursor into the reaction chamber; and,
flowing a hydrogen precursor into the reaction chamber to deposit molybdenum on the molybdenum nitride.

6. The method of claim 1, wherein the molybdenum precursor comprises at least one of: a molybdenum halide precursor; a molybdenum chloride precursor; a molybdenum iodide precursor; a molybdenum bromide precursor; a molybdenum chalcogenide; a molybdenum oxychloride; a molybdenum oxyiodide; a molybdenum (IV) dichloride dioxide (MoO₂Cl₂) precursor; or a molybdenum oxybromide.

7. The method of claim 1, wherein the nitrogen precursor comprises ammonia (NH₃) or hydrazine (N₂H₄).

8. The method of claim 1, wherein a temperature of the reaction chamber is between 300° C. and 500° C., preferably between 350° C. and 450° C., and a pressure in the reaction chamber is between 100 and 2000 millitorr, preferably between 200-1500 millitorr during the cleaning run.

9. The method of claim 1, wherein a pressure of the reaction chamber is between 1 and 200 Torr, preferably between 5 to 100 Torr and a temperature of the reaction chamber is between 450° C. and 650° C., preferably between 500° C. and 600° C. during the molybdenum nitride deposition run.

10. The method of claim 1, further comprising a molybdenum conditioning run after the cleaning run, the molybdenum conditioning run comprising:
flowing a molybdenum precursor into the reaction chamber; and,
flowing a hydrogen precursor or a nitride precursor into the reaction chamber to deposit molybdenum or molybdenum nitride in the reaction chamber.

11. The method of claim 1, wherein removing the plurality of wafers in the wafer boat from the reaction chamber comprises:
removing the boat with wafers in a substantial vertical direction from the reaction chamber of the vertical furnace;
removing the wafers from the boat; and,
loading the boat in a substantial vertical direction into the reaction chamber of the vertical furnace.

12. The method of claim 1, wherein the cleaning run is repeated after every deposition run.

13. The method of claim 1, wherein the vertical furnace is only depositing molybdenum nitride on the wafers and the cleaning run is repeated after every deposition run.

14. The method of claim 1, wherein the vertical furnace is depositing a combination of molybdenum nitride and molybdenum layers on the wafers and the cleaning run is repeated after 2 to 10 deposition runs or 3 to 6 deposition runs.

15. The method of claim 1, wherein the deposition run comprises flowing the molybdenum precursor through a first injector into the reaction chamber and flowing the nitrogen precursor through a second injector into the reaction chamber; and the cleaning run comprises flowing the cleaning gas through a third injector into the reaction chamber.

16. The method of claim 1, wherein the deposition run comprises:
flowing the molybdenum precursor through a first injector into the reaction chamber; and,
flowing the nitrogen precursor through the same first injector into the reaction chamber, and the cleaning run comprises flowing the cleaning gas through the same first injector into the reaction chamber.

17. The method of claim 1, wherein the method comprises:
measuring a thickness of the layer deposited in the reaction chamber during the cleaning run; and,
stopping the cleaning run by stopping the flow of the cleaning gas when the measured thickness of the layer deposited in the reaction chamber is substantially zero.

18. The method according to claim 1, wherein flowing the molybdenum precursor into the reaction chamber is done simultaneously with flowing the nitrogen precursor into the reaction chamber to deposit molybdenum nitride on the wafers in the wafer boat.

19. The method according to claim 1, wherein the molybdenum nitride deposition run comprises flowing hydrogen into the reaction chamber.

20. A vertical furnace for depositing a molybdenum or molybdenum nitride layer, the vertical furnace comprising:
a reaction chamber configured to hold a plurality of substrates and provided with a heater to process the wafers in the wafer boat;
a first precursor source configured to provide a molybdenum precursor to the reaction chamber via a first valve;
a second precursor source configured to provide a nitrogen precursor to the reaction chamber via a second valve;
a cleaning gas source configured to provide a cleaning gas to the reaction chamber via a third valve;
a wafer handler to transfer wafers to and from the wafer boat;
a boat loader to load and unload the wafer boat in a substantial vertical direction into or out of the reaction chamber of the vertical furnace; and,
a controller provided with a memory and constructed and arranged to control the first, second and third valve, the heater, the wafer handler and the boat loader, wherein the memory is programmed with a program when run on the controller to execute a method according to claim 1.
